(19) United States
(12) Patent Application Publication
(10) Pub. No.: US 2007/0037317 A1
(43) Pub. Date: Feb. 15, 2007

(54) Method and device for attaching a chip in a housing

(76) Inventors: Klaus Offterdinger, Stuttgart (DE); Ronny Ludwig, Reutlingen (DE)

Correspondence Address: KENYON & KENYON LLP, ONE BROADWAY, NEW YORK, NY, 10004, US

(21) Appl. No.: 10/574,189

(22) PCT Filed: Sep. 15, 2004
(86) PCT No.: PCT/DE04/02054

§ 371 Date: Mar. 31, 2006

(30) Foreign Application Priority Data
Oct. 16, 2003 (DE) 10348253.9

(51) Int. Cl. H01L 21/00

(52) U.S. Cl. 438/106

(57) ABSTRACT

A method and the associated device for attaching at least one micromechanical chip in a housing which is optically transparent to radiation of at least one predefined transmission wavelength, in which an adhesive layer is applied between the chip and the housing and the adhesive layer is irradiated through the housing using radiation of the transmission wavelength for the purpose of curing.

### BACKGROUND INFORMATION

Premold housings are chip housings which are manufactured in molding methods by extrusion coating a carrier strip (in the following: lead frame) with plastic or a molding compound (based on epoxide resin, for example). These materials are identical in color to the standard molded housings thus manufactured (frequently: black, white, beige, etc.), so that the subsequent construction within the housing is not visible from the outside after completion.

Usually, chips which may not be completely extrusion-coated with plastic or molding compound because of their properties are mounted in premold housings. Because of non-transparent premold housings, these chips are mounted using an adhesive having a cross-linking mechanism based on the effect of heat.

### SUMMARY

The present invention relates to a method for attaching at least one chip in a housing which is optically transparent to radiation of at least one predefined transmission wavelength, in which an adhesive layer is applied between the chip and the housing and the adhesive layer is irradiated through the housing using radiation of the transmission wavelength for the purpose of curing.

The manufacturing method is thus made significantly easier in regard to the attachment.

In accordance with an advantageous embodiment of the present invention, the housing is a premold housing or plastic housing which is transparent to radiation in the visible range and/or in the ultraviolet range.

In accordance with an advantageous embodiment of the present invention, the adhesive layer is made of an adhesive which cures especially well under ultraviolet or visible light.

In accordance with an advantageous embodiment of the present invention, the radiation is light in the visible range or in the ultraviolet range.

In accordance with an advantageous embodiment of the present invention, the radiation comes from the side facing away from the chip and hits the adhesive layer. The radiation therefore does not have to pass through the chip first.

Furthermore, the present invention relates to a system including a chip in a housing which is optically transparent to radiation of at least one predefined transmission wavelength and an adhesive layer between the chip and the housing, the adhesive layer being cured via irradiation through the housing using radiation of the transmission wavelength.

A device according to an example embodiment of an example embodiment of the present invention for attaching at least one (e.g., micromechanical) chip in a housing which is optically transparent to radiation of at least one predefined transmission wavelength may include a radiation source which may be positioned in relation to the housing in such a way that an adhesive layer located between the chip and the housing is irradiated by the radiation source through the housing using radiation of the transmission wavelength for the purpose of curing.

Advantageous embodiments of the method according to the present invention are also expressed as advantageous embodiments of the device according to the present invention and the system according to the present invention and vice versa.

Multiple chips may also be mounted and/or attached in a premold housing using the method according to the present invention.

The following advantages may result because the material used for manufacturing premold housings and/or plastic housings is optically transparent (clear):
The chips subsequently packaged in optically transparent premold housings may be glued using an adhesive which may be cured using UV light or even visible light via irradiation through the housing from the bottom.
UV-curing or light-curing adhesive systems cross-link extremely rapidly in comparison to thermally cross-linking adhesive systems. Therefore, very short manufacturing times and lower manufacturing costs result.
Mechanical strains between the chip and the premold housing, which frequently arise in the case of thermally cross-linking adhesives due to the different thermal expansion coefficients of the materials, may be avoided with adhesive systems which cross-link under ultraviolet or visible light because of an equal temperature level.
Due to the optical transparency of the premold housing, simple inspection and/or error checking is possible, e.g., checking for bubbles, inclusions, and shrinkage cavities in the used adhesive before and after it cures, and checking the loop shape of the wire connections by looking laterally into the housing, etc.
Frequently, “spacers” are mixed into adhesives (spacers are small round balls having a defined diameter), which allow a precise adhesive thickness between the chip and housing. The distribution of the spacers in the adhesive after the curing step may be checked and/or measured using an optically transparent premold housing.
Simple three-dimensional optical analysis in the development of novel applications is possible without destroying the housing.
There is high acceptance of premold housings. (Customer acceptance may even be increased by replacing a “black box” with an optically transparent premold housing for a customer product.)
Fields of application of optically clear premold housings in the automobile field are readily possible if optically transparent molding compounds for injection molding machines are used which have a high thermal dimensional stability, very high strength and rigidity, and good weather resistance (e.g.: poly n-methyl methacrylamide, or PMMI, having dimensionally stable temperatures up to 170° C.).

### BRIEF DESCRIPTION OF THE DRAWINGS

FIG. 1 shows an example of a premold housing made of optically transparent material (i.e., transparent material) without a metallic insert (referred to in the following as a “diepad”) under the chip adhesive region. The upper partial figure in FIG. 1 shows a lateral section through the housing (i.e., a section in the lateral view plane), and the lower partial figure shows a horizontal section through the housing (i.e., a section in the top view plane).

FIG. 2 shows an example of a premold housing made of optically transparent material (i.e., transparent material) having a structured, i.e., a partially optically transparent, diepad. This diepad may be used as the EMC protector (EMC=“electromagnetic compatibility”) upon electrical contact. FIG. 3 shows the principle of curing a UV-curing or light-curing adhesive system through the premold housing.

### DESCRIPTION OF EXAMPLE EMBODIMENTS

The present invention relates to optically transparent premold housings. Some possible advantages of optically transparent premold housings are described on the basis of a housing example. These are made of optically transparent plastic materials or optically transparent molding compounds.

The premold housing is manufactured from an optically transparent material (injectable plastics or optically clear molding compounds).

It is therefore possible to use UV-curing and light-curing adhesive systems and curing them via irradiation through the housing material. Many possible advantages of this adhesive technology are described above.

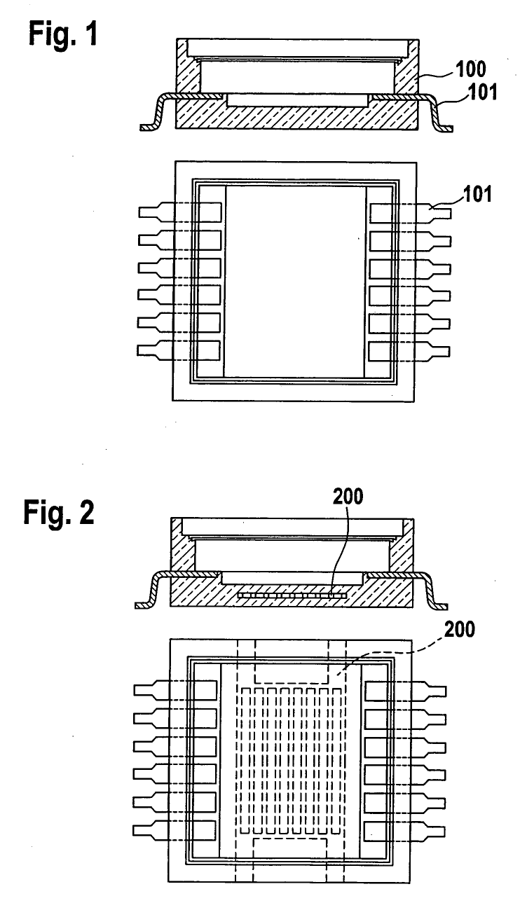

In FIG. 1, the side view of a premold housing without a diepad is shown on top and the top view is shown below. In this case, 100 identifies the housing, which is made of transparent plastic or a transparent molding compound. 101 identifies the terminal contacts, which lead outward.

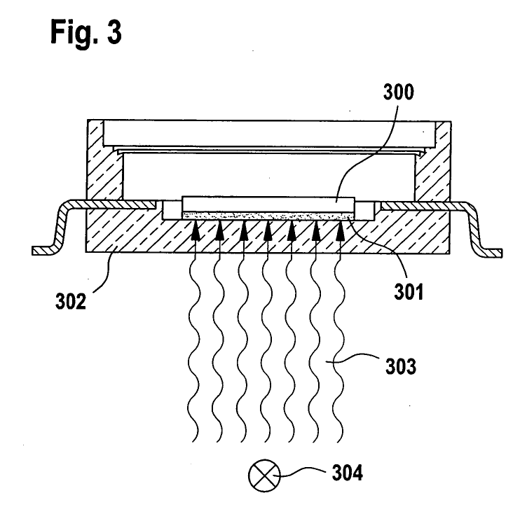

The same housing, additionally including a diepad 200, is illustrated in FIG. 2. In this exemplary embodiment, the diepad is a metallic grid. The surface of the diepad is more even than a plastic surface, therefore the chip may be glued thereon in a more precise position.

FIG. 3 shows a chip 300, which is inserted into a housing as shown in FIG. 1 (without a diepad). An adhesive layer 301 is located between chip 300 and housing 302. This layer is made of an adhesive which is cured by UV light or visible light. External radiation 303 hits adhesive layer 301 through optically transparent housing 302. This radiation is emitted by a radiation source 304. The transparency of the housing to this radiation is consciously exploited here. The type of radiation 303 used (UV, visible light, . . . ) depends on the cross-linking mechanism of the adhesive used.

1-8. (canceled)

9. A method for attaching at least one chip in a housing, the housing being optically transparent to radiation of at least one predefined transmission wavelength, the method comprising:
applying an adhesive layer between the at least one chip and the housing; and
irradiating the adhesive layer through the housing using radiation of the transmission wavelength for curing.

10. The method as recited in claim 9, wherein the housing is a premold housing or a plastic housing which is transparent to radiation in at least one of a visible range and an ultraviolet range.

11. The method as recited in claim 10, wherein the radiation is light in the visible range or in the ultraviolet range.

12. The method as recited in claim 9, wherein the radiation comes from a side facing away from the chip and hits the adhesive layer.

13. The method as recited in claim 9, wherein the adhesive layer is made of an adhesive which cures under ultraviolet or visible light.

14. A system, comprising:
at least one chip in a housing, the housing being optically transparent to radiation of at least one predefined transmission wavelength; and
an adhesive layer between the at least one chip and the housing, the adhesive layer being cured via irradiation through the housing using radiation of the transmission wavelength.

15. The system as recited in claim 14, wherein the at least one chip is a micromechanical chip.

16. A device for attaching at least one chip in a housing, the housing being optically transparent to radiation of at least one predefined transmission wavelength, comprising:
a radiation source which is positioned in relation to the housing so that an adhesive layer located between the at least one chip and the housing is irradiated through the housing by radiation of the transmission wavelength from the radiation source for curing.
